(19) United States
(12) Patent Application Publication
(10) Pub. No.: US 2026/0011355 A1
(43) Pub. Date: Jan. 8, 2026

(54) MEMORY DEVICE AND METHOD OF APPLYING AN UNDERDRIVE VOLTAGE

(71) Applicant: SK hynix Inc., Icheon-si Gyeonggi-do (KR)

(72) Inventors: Eun Woo JO, Icheon-si Gyeonggi-do (KR); Da U Ni KIM, Icheon-si Gyeonggi-do (KR)

(73) Assignee: SK hynix Inc., Icheon-si Gyeonggi-do (KR)

(21) Appl. No.: 19/041,589

(22) Filed: Jan. 30, 2025

(30) Foreign Application Priority Data
Jul. 3, 2024 (KR) 10-2024-0087477

(51) Int. Cl. G11C 8/10

(52) U.S. Cl. CPC G11C 8/10

(57) ABSTRACT

A memory device including a memory cell array having memory cells connected to a selected word line, a first voltage regulator configured to generate an underdrive voltage lower than an operating voltage, an address decoder including transistors, and configured to apply, to the selected word line, a voltage received during an underdrive period, a second voltage regulator configured to generate a well voltage to be applied to the transistors, a voltage transfer circuit configured to transfer the underdrive voltage or the well voltage to the address decoder, and a control logic configured, in response to the underdrive voltage being at a negative level, to control the second voltage regulator to set the well voltage to the negative level before the underdrive period, and to control the voltage transfer circuit to transfer the well voltage set to the negative level to the address decoder during the underdrive period.

### CROSS-REFERENCE TO RELATED APPLICATION

The present application claims priority under 35 U.S.C. § 119(a) to Korean patent application number 10-2024-0087477 filed on Jul. 3, 2024, in the Korean Intellectual Property Office, the entire contents of which application is incorporated herein by reference.

### BACKGROUND

### 1. Technical Field

Various embodiments of the present disclosure generally relate to a memory device, and more particularly to a memory device and a method of applying an underdrive voltage to a selected word line.

### 2. Related Art

Memory devices are classified into volatile memory devices and non-volatile memory devices. A volatile memory device is a memory device, which stores data only when power is supplied thereto, and in which data stored therein is lost when power is turned off. A non-volatile memory device may be a memory device configured to retain data even when the power is turned off.

Memory devices may perform a read operation of reading data stored in a memory cell. During the read operation, the memory device may perform an underdrive operation before applying a read voltage to a word line connected to the memory cell. Here, the underdrive operation is an operation of lowering a voltage level of the word line. In some embodiments, the underdrive operation is an operation of lowering a voltage level of the word line and aims to improve the setting of the word line.

Effects of the underdrive operation may vary depending on the time it takes to change the voltage of the word line during the underdrive operation.

### SUMMARY

An embodiment of the present disclosure may provide for a memory device. The memory device may include a memory cell array including memory cells connected to a selected word line, a first voltage regulator configured to generate an underdrive voltage having a voltage level lower than an operating voltage applied to the selected word line, an address decoder including a plurality of transistors, and configured to apply, to the selected word line, a voltage received during an underdrive period during which the underdrive voltage is applied to the selected word line, a second voltage regulator configured to generate a well voltage to be applied to the plurality of transistors, a voltage transfer circuit configured to transfer the underdrive voltage or the well voltage to the address decoder, and a control logic configured, in response to the underdrive voltage being at a negative level, to control the second voltage regulator to set the well voltage to the negative level before the underdrive period, and to control the voltage transfer circuit to transfer the well voltage set to the negative level to the address decoder during the underdrive period.

An embodiment of the present disclosure may provide for a method of operating a memory device. The method may include, based on an operating voltage applied to memory cells connected to a selected word line, determining an underdrive period during which an underdrive voltage lower than the operating voltage is applied to the selected word line, in response to the underdrive voltage being at a negative level, setting a well voltage applied to transistors included in an address decoder to the negative level, and in response to the underdrive voltage being at a negative level, applying the well voltage to the selected word line during the underdrive period.

An embodiment of the present disclosure may provide for a method of operating a memory device. The method may include determining a first underdrive period during which a first underdrive voltage lower than a first operating voltage to be applied to memory cells connected to a selected word line is applied to the selected word line, in response to the first underdrive voltage to be generated from a first voltage regulator configured to generate the first operating voltage being at a first negative level, generating a first well voltage corresponding to the first underdrive voltage earlier by a first time period than the first underdrive period by a second voltage regulator configured to generate a well voltage to be applied to transistors included in an address decoder, applying the first well voltage generated from the second voltage regulator to the selected word line during the first underdrive period, determining a second underdrive period during which a second underdrive voltage lower than a second operating voltage applied to the memory cells is applied to the selected word line, in response to the second underdrive voltage to be generated from the first voltage regulator being at a second negative level, generating by the second voltage regulator a second well voltage corresponding to the second underdrive voltage earlier by a second time period than the second underdrive period, and applying the second well voltage generated from the second voltage regulator to the selected word line during the second underdrive period.

### BRIEF DESCRIPTION OF THE DRAWINGS

FIG. 1 is a diagram illustrating a memory device according to an embodiment of the present disclosure.

FIG. 2 is a diagram illustrating connection between voltage regulators and an address decoder according to an embodiment of the present disclosure.

FIG. 3 is a diagram illustrating a voltage transfer circuit including a switch according to an embodiment of the present disclosure.

FIG. 4 is a diagram illustrating characteristics of a well voltage according to an operating voltage.

FIG. 5 is a diagram illustrating an underdrive voltage according to an embodiment of the present disclosure.

FIG. 6 is a diagram illustrating a method of applying underdrive voltages of a negative level to a selected word line according to an embodiment of the present disclosure.

FIG. 7 is a flowchart illustrating a method of applying an underdrive voltage to a selected word line according to an embodiment of the present disclosure.

### DETAILED DESCRIPTION

Specific structural or functional descriptions in the embodiments of the present disclosure introduced in this specification or application are provided as examples to describe embodiments according to the concept of the present disclosure. The embodiments according to the concept of the present disclosure may be practiced in various forms, and should not be construed as being limited to the embodiments described in the specification or application. In the description of the present disclosure, the terms “first” and “second” may be used to describe various components, but the components are not limited by the terms. The terms may be used to distinguish one component from another component. For example, a first component may be called a second component and a second component may be called a first component without departing from the scope of the present disclosure.

Various embodiments of the present disclosure are directed to a memory device and a method of applying an underdrive voltage, in which an underdrive voltage is pre-generated, and the pre-generated underdrive voltage is applied through a switching operation during an underdrive operation period.

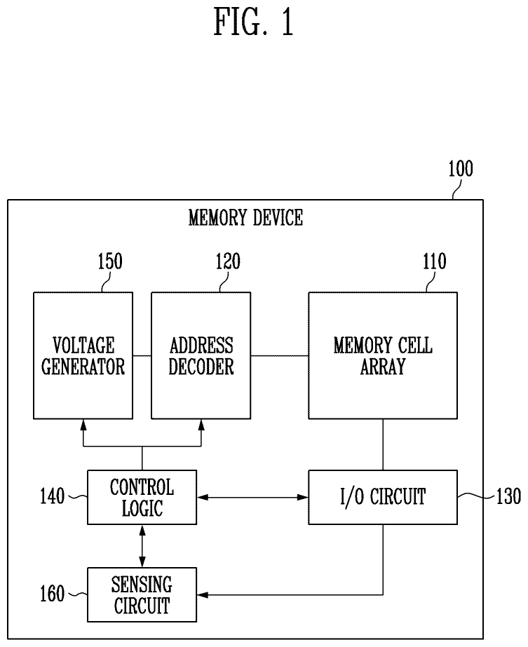

FIG. 1 is a diagram illustrating a memory device according to an embodiment of the present disclosure.

Referring to FIG. 1, a memory device 100 may store data. The memory device 100 may include a memory cell array 110 including memory cells which store data, an address decoder 120 which decodes a column address, an input/output (I/O) circuit 130 which transmits/receives data to/from an external system of the memory device 100, a control logic 140, and a voltage generator 150 which generates a plurality of voltages having various voltage levels. The control logic 140 may be implemented as hardware, software, or a combination of hardware and software. For example, the control logic 140 may be a control logic circuit operating in accordance with an algorithm and/or a processor executing control logic code.

Each of the memory cells included in the memory cell array 110 may be a single-level cell (SLC) which stores 1-bit data, or a memory cell which stores multi-bit data. The memory cell which stores the multi-bit data may be a multi-level cell (MLC) which stores 2-bit data, a triple-level cell (TLC) which stores 3-bit data, or a quad-level cell (QLC) which stores 4-bit data depending on the number of bits in the multi-bit data.

The address decoder 120 may be connected to the memory cell array 110 through word lines. The address decoder 120 may decode an address received from the input/output circuit 130 to select a word line. The address decoder 120 may apply a voltage received from the voltage generator 150 to the selected word line. The address decoder 120 may operate in response to a control signal received from the control logic 140.

The input/output circuit 130 may include page buffers configured to read data stored in the memory cells and store the read data. The input/output circuit 130 may output the data stored in the page buffers to the external device of the memory device 100, or store data received from the external device in the page buffers and then store the received data in the memory cells.

The control logic 140 may control the overall operation of the memory device 100. The control logic 140 may generate control signals for controlling the address decoder 120, the input/output circuit 130, and the voltage generator 150 to perform a read operation, a program operation, and an erase operation for the memory cell array 110.

The voltage generator 150 may generate voltages needed to perform operations of the memory device 100. The voltage generator 150 may include voltage regulators configured to generate voltages having various potentials. The voltage generator 150 may generate a program voltage, a verify voltage, and a read voltage required from the memory device 100. Voltages generated from the voltage generator 150 may be supplied to the memory cells included in the memory cell array 110 through the address decoder 120.

The sensing circuit 160 may determine whether a verify operation for a specific program state has passed, based on an applied verify voltage. For example, the sensing circuit 160 may generate reference current in response to an enable bit signal during the verify operation, and may compare a reference voltage generated by the reference current with a sensing voltage received from each of the page buffers and then output a pass signal or a fail signal. As another example, the sensing circuit 160 may generate a reference voltage in response to an enable bit signal during the verify operation, and may compare reference current generated by the reference voltage with sensing current received from each of the page buffers and then output a pass signal or a fail signal.

In an embodiment of the present disclosure, the address decoder 120, the input/output circuit 130, and the voltage generator 150 may be referred to as peripheral circuits. The control logic 140 may control the peripheral circuits to perform operations on the memory cells included in the memory cell array 110.

In an embodiment of the present disclosure, the voltage generator 150 may include an operating voltage regulator configured to generate operating voltages to be applied to the memory cells, and a well voltage regulator configured to generate a well voltage to be applied to transistors included in the address decoder 120. The operating voltages may include a program voltage, an erase voltage, and a read voltage. The well voltage may be applied to a body of each of the transistors. The well voltage may prevent or mitigate bias from being generated between a junction and a well of the transistor.

In an embodiment of the present disclosure, the control logic 140 may control the peripheral circuits to perform an underdrive operation. The control logic 140 may transfer an underdrive voltage generating signal to the voltage generator 150 to generate an underdrive voltage lower than an operating voltage. The control logic 140 may transfer an underdrive operating signal to the address decoder 120 and control the address decoder 120 to perform an underdrive operation of applying, to a selected word line, an underdrive voltage received before applying the operating voltage. In an embodiment, an underdrive voltage is a voltage that is applied to the selected word line before applying a voltage to the selected word line for an operating voltage (i.e., a corresponding operating voltage). In an embodiment, the underdrive voltage is a voltage that is lower than the voltage for the operating voltage. For example, when the voltage for the operation voltage is a positive voltage the voltage for the underdrive voltage is a positive or negative voltage and is lower than the operation voltage. For example, when the voltage for the operation voltage is a negative voltage the voltage for the underdrive voltage is a negative voltage that is less than or more negative than the operation voltage. For example, before applying a program voltage an underdrive voltage may be applied to the selected word line and the underdrive voltage is lower than the program voltage. For example, before applying an erase voltage an underdrive voltage may be applied to the selected word line and the underdrive voltage is lower than the erase voltage. For example, before applying a read voltage an underdrive voltage may be applied to the selected word line and the underdrive voltage is lower than the read voltage.

In the case where the underdrive voltage is at a negative level, the control logic 140 may pre-generate an underdrive voltage using the well voltage regulator. The control logic 140 may control the transfer of an underdrive voltage, generated from the well voltage regulator, to an address decoder 120. The control logic 140 may use a voltage transfer circuit 153 to control the transfer from the well voltage regulator to the address decoder by using a voltage transfer circuit 153. The control logic 140 may control a switching operation of the voltage transfer circuit 153 to allow the underdrive voltage to be received by the address decoder 120. Then, he address decoder 120 may apply the received underdrive voltage to the selected word line. The voltage of the selected word line may be changed to the applied underdrive voltage without a settling time.

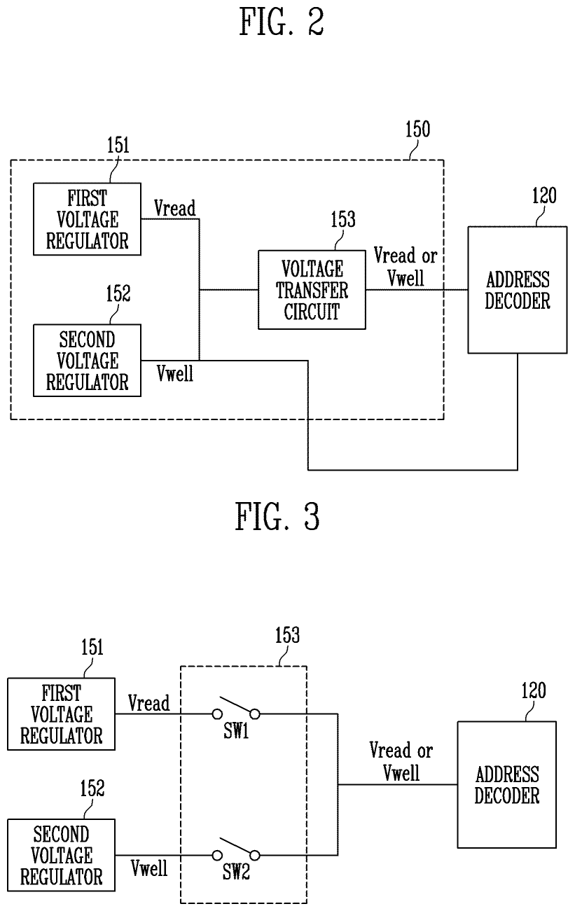

FIG. 2 is a diagram illustrating connection between voltage regulators and an address decoder according to an embodiment of the present disclosure.

Referring to FIG. 2, the voltage generator 150 may include a first voltage regulator 151, a second voltage regulator 152, and a voltage transfer circuit 153. The voltage generator 150 may transfer a generated voltage to the address decoder 120.

In FIG. 2, the first voltage regulator 151 may be an operating voltage regulator, and the second voltage regulator 152 may be a well voltage regulator. Hereinafter, for convenience of description, it is assumed that an operating voltage generated by the first voltage regulator 151 is a read voltage Vread. In an embodiment, the first voltage regulator 151 generates the underdrive voltage corresponding to an operating voltage that is to be generated by the first voltage regulator 151.

The voltage transfer circuit 153 may transfer voltages received from the first voltage regulator 151 and the second voltage regulator 152 to the address decoder 120. In other words, the voltage transfer circuit 153 may transfer a read voltage Vread or a well voltage Vwell to the address decoder 120.

Although not illustrated in FIG. 2, the control logic 140 may transmit control signals to the first voltage regulator 151 and the second voltage regulator 152 to control levels and timings of voltages to be generated. The control logic 140 may transmit a switching signal to the voltage transfer circuit 153 to set a voltage to be transferred from the voltage transfer circuit 153 to the address decoder 120.

The first voltage regulator 151 may generate a read voltage Vread, and transmit the read voltage Vread to the voltage transfer circuit 153. The second voltage regulator 152 may generate a well voltage Vwell, and transmit the well voltage Vwell to the voltage transfer circuit 153. The well voltage Vwell may be a well voltage Vwell to be applied to the transistors included in the address decoder 120. The well voltage Vwell may be a voltage to be applied to the body of each of the transistors.

The read voltage Vread generated from the first voltage regulator 151 may be transferred to the address decoder 120 through the voltage transfer circuit 153. The address decoder 120 may apply the received read voltage Vread to memory cells through a selected word line. In an embodiment of the present disclosure, an underdrive operation of applying an underdrive voltage lower than the read voltage Vread may be performed before the application of the read voltage Vread. In an embodiment, the underdrive operation may be an operation of applying a preset voltage, that is the underdrive voltage, to the selected word line to reduce the voltage level of the selected word line. The word “preset” as used herein with respect to a parameter, such as a preset voltage or preset time, means that a value for the parameter is determined prior to the parameter being used in a process or algorithm. For some embodiments, the value for the parameter is determined before the process or algorithm begins. In other embodiments, the value for the parameter is determined during the process or algorithm but before the parameter is used in the process or algorithm.

The control logic 140 may control the second voltage regulator 152 to set the well voltage Vwell to a negative level in response to the underdrive voltage being at a negative level lower than the read voltage. The second voltage regulator 152 may generate a well voltage Vwell with a negative level, and transfer the well voltage Vwell with the negative level to the voltage transfer circuit 153.

The control logic 140 may control the second voltage regulator 152 to generate a well voltage Vwell with a negative level before an underdrive period during which an underdrive voltage is applied to the selected word line. Taking into account a settling time for the well voltage Vwell to reach a negative level, the control logic 140 may transmit a well voltage control signal to the second voltage regulator 152. The well voltage Vwell generated from the second voltage regulator 152 may be a well voltage Vwell having a negative level before the underdrive period.

The settling time for the well voltage Vwell to reach a negative level may vary depending on the magnitude of the negative level. As the magnitude of the negative level increases, the settling time increases. The control logic 140 may determine a timing for transferring the well voltage control signal to the second voltage regulator 152 such that the timing becomes earlier as the magnitude of the negative level increases. In another embodiment of the present disclosure, the control logic 140 may transmit a well voltage control to the second voltage regulator 152 when a previous read voltage is applied to the selected word line, to ensure a sufficient setting time for the well voltage Vwell to reach a negative level.

In an embodiment of the present disclosure, the voltage transfer circuit 153 may transfer the read voltage Vread or the well voltage Vwell to the address decoder 120. The voltage to be transferred from the voltage transfer circuit 153 to the address decoder 120 may be determined based on the level of the underdrive voltage. In detail, in the case where the underdrive voltage is at a positive level, the voltage transfer circuit 153 may transfer the read voltage Vread generated from the first voltage regulator 151 to the address decoder 120. In this case, the connection between the second voltage regulator 152 and the voltage transfer circuit 153 may be released.

In the case where the underdrive voltage is at a negative level, the voltage transfer circuit 153 may transfer the well voltage Vwell with a negative level, generated from the second voltage regulator 152, to the address decoder 120. In this case, the connection between the first voltage regulator 151 and the voltage transfer circuit 153 may be released.

FIG. 3 is a diagram illustrating a voltage transfer circuit including a switch according to an embodiment of the present disclosure.

Referring to FIG. 3 the voltage transfer circuit 153 may include a first switch SW1 and a second switch SW2. The first switch SW1 may connect the first voltage regulator 151 to the address decoder 120. The second switch SW2 may connect the second voltage regulator 152 to the address decoder 120. In an embodiment of the present disclosure, the first switch SW1 and the second switch SW2 may be implemented using transistors. In the following descriptions pertaining to FIG. 3, redundant descriptions overlapping those of FIG. 2 will be omitted.

The control logic 140 may generate a switching signal to control on/off of the first switch SW1 and the second switch SW2 included in the voltage transfer circuit 153. In the case where the underdrive voltage is at a positive level, the control logic 140 may generate a first switching signal to turn on the first switch SW1 and turn off the second switch SW2. Here, a read voltage Vread generated from the first voltage regulator 151 may be transferred to the address decoder 120, while a well voltage Vwell generated from the second voltage regulator 152 is not transferred to the address decoder 120. In an embodiment, the voltage transfer circuit 153 is configured to transfer voltage received from the first voltage regulator 151 or the second voltage regulator 152 to the address decoder 120. In an embodiment, a negative level is a voltage having a value that is less than zero. In an embodiment, a positive level is a voltage having a value that is greater than or equal to zero.

Similarly, in the case where the underdrive voltage is at a negative level, the control logic 140 may generate a second switching signal to turn off the first switch SW1 and turn on the second switch SW2. Here, a well voltage Vwell generated from the second voltage regulator 152 may be transferred to the address decoder 120, while a read voltage Vread generated from the first voltage regulator 151 is not transferred to the address decoder 120.

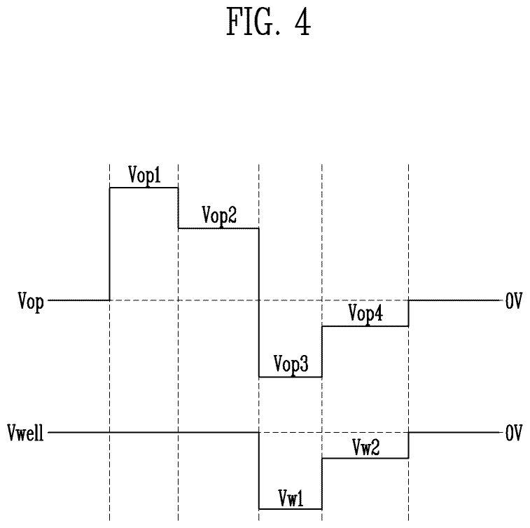

FIG. 4 is a diagram illustrating characteristics of a well voltage according to an operating voltage.

Referring to FIG. 4, there is illustrated a well voltage Vwell applied to the transistors included in the address decoder 120 according to an operating voltage Vop. The well voltage Vwell may be applied to the body of each of the transistors, thus preventing or mitigating bias from being generated between the junction and the well.

In FIG. 4, it may be assumed that first to fourth operating voltages Vop1, Vop2, Vop3, and Vop4 may be applied. The first voltage regulator 151 may generate first to fourth operating voltages Vop1, Vop2, Vop3, and Vop4 having different voltage levels. The second voltage regulator 152 may generate well voltages Vw1 and Vw2 in response to the first to fourth operating voltages Vop1, Vop2, Vop3, and Vop4.

The well voltages Vw1 and Vw2 may be at the same level as the operating voltage Vop when the operating voltage Vop is at a negative level, and may be at the ground voltage or 0 V when the operating voltage Vop is at a positive level. In FIG. 4, a third operating voltage Vop3 may be the same as the first well voltage Vw1, and a fourth operating voltage Vop4 may be the same as the second well voltage Vw2.

An underdrive voltage corresponding to the operating voltage Vop may have a voltage level lower than the operating voltage Vop. In the case where the operating voltage Vop is at a negative level, the underdrive voltage corresponding to the operating voltage Vop may also be at a negative level. In an embodiment of the present disclosure, the control logic may determine whether the underdrive voltage is at a negative voltage, based on the operating voltage Vop.

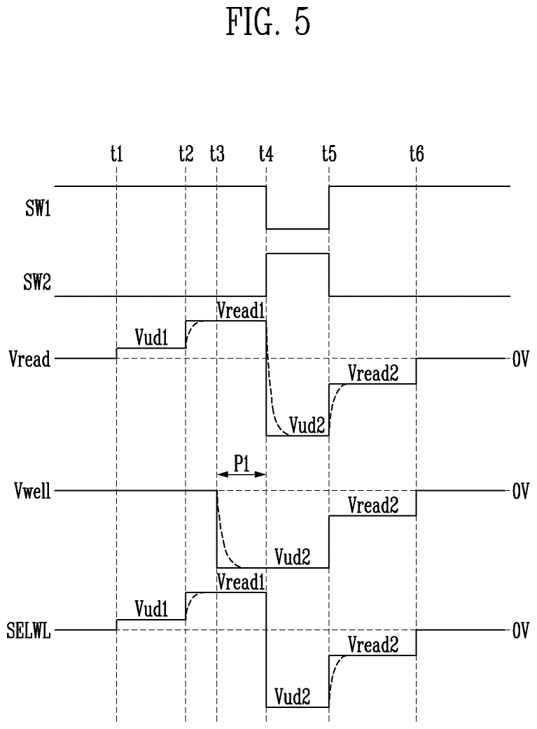

FIG. 5 is a diagram illustrating an underdrive voltage according to an embodiment of the present disclosure.

Referring to FIG. 5, there are illustrated a read voltage Vread generated from the first voltage regulator 151, a well voltage Vwell generated from the second voltage regulator 152, and a selected word line voltage SELWL corresponding to the operation of the first and second switches SW1 and SW2 included in the voltage transfer circuit 153. In FIG. 5, a solid line may represent an ideal voltage level, and a dotted line may represent a realistic voltage level reflecting a settling time.

The first voltage regulator 151 may generate a first underdrive voltage Vud1 during a period from t1 to t2, and may generate a first read voltage Vread1 during a period from t2 to t4. The first voltage regulator 151 may generate a second underdrive voltage Vud2 during a period from t4 to t5, and may generate a second read voltage Vread2 during a period from t5 to t6. The control logic 140 may determine the period from t1 to t2 as a first underdrive period, and the period from t4 to t5 as a second underdrive period.

Because the first underdrive voltage Vud1 is at a positive level, the well voltage Vwell is maintained at 0 V during a period from t1 to t3. Because the second underdrive voltage Vud2 is at a negative level, the control logic 140 may generate a well voltage control signal to set the well voltage Vwell to Vud2. The control logic 140 may transmit a well voltage control signal to the second voltage regulator 152 at time t3 so that a sufficient settling time P1 is secured based on the magnitude of a negative voltage. In FIG. 5, P1 may represent a settling time, which is the time required for the well voltage Vwell to change from 0 V to Vud2.

Although at time t4 the well voltage Vwell generated from the second voltage regulator 152 reaches Vud2, which is a negative level, the read voltage Vread generated from the first voltage regulator 151 may reach Vud2 between time t4 and time t5. The control logic 140 may control the operation of the first to second switches SW1 and SW2 so that the well voltage Vwell is connected to the address decoder 120 only during the second underdrive period.

In FIG. 5, there is illustrated a selected word line voltage SELWL according to the operation of the first and second voltage regulators 151 and 152 and the voltage transfer circuit 153. During the second underdrive period, due to the well voltage Vwell transferred to the address decoder 120, the selected word line voltage SELWL at time t4 may be at the negative level Vud2 without a settling time.

Although an embodiment in which the control logic 140 transmits a well voltage control signal to the second voltage regulator 152 at time t3 is illustrated in FIG. 5, it is sufficient for the well voltage control signal to be transmitted before time t3. In another embodiment of the present disclosure, the well voltage control signal may be transmitted to the second voltage regulator to secure a sufficient settling time at a time point (i.e., time t2 in FIG. 5) at which the first read voltage Vread1 applied before the second underdrive period is applied to the selected word line.

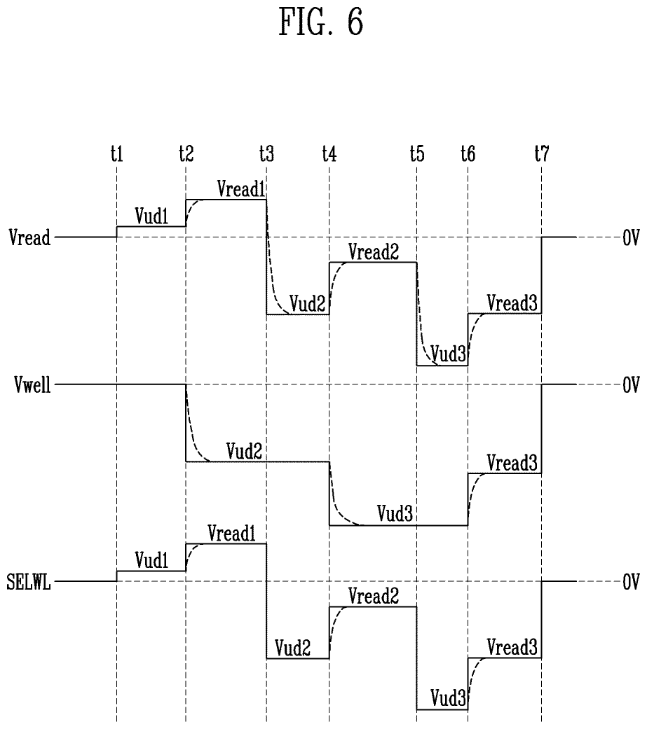

FIG. 6 is a diagram illustrating a method of applying underdrive voltages of a negative level to a selected word line according to an embodiment of the present disclosure.

Referring to FIG. 6, there is illustrated the case where first to third read voltages Vread1, Vread2, and Vread3 are applied to the address decoder 120, and underdrive voltages Vud2 and Vud3 with negative levels are applied to the selected word line without a settling time. In the following descriptions pertaining to FIG. 6, redundant descriptions overlapping those of FIG. 5 will be omitted.

The control logic 140 may determine a period from t1 to t2 as a first underdrive period, a period t3 to t4 as a second underdrive period, and a period from t5 to t6 as a third underdrive period. Because the first underdrive voltage Vud1 is at a positive level, a well voltage Vwell is not transferred to the address decoder 120 during the first underdrive period.

The control logic 140 may transmit a first well voltage control signal to the second voltage regulator, in response to the second underdrive voltage Vud2 having a first negative level. The first well voltage control signal may be a signal instructing the second voltage regulator 152 to set the well voltage Vwell to the first negative level. In FIG. 6, the control logic 140 may transmit the first well voltage control signal to the second voltage regulator at time t2 at which the first read voltage Vread1 is generated. A sufficient settling time in which the well voltage Vwell is set to the first negative level may be secured.

The control logic 140 may transmit a second well voltage control signal to the second voltage regulator, in response to the third underdrive voltage Vud3 having a second negative level. The second well voltage control signal may be a signal instructing the second voltage regulator 152 to set the well voltage Vwell to the second negative level. In FIG. 6, the control logic 140 may transmit the second well voltage control signal to the second voltage regulator at time t4 at which the second read voltage Vread2 is generated.

Although not illustrated in FIG. 6, the voltage transfer circuit 153 may perform a switching operation so that the well voltage Vwell is transferred to the address decoder 120 only during the second underdrive period and the third underdrive period. The address decoder 120 may apply the received well voltage Vwell to the selected word line. Because the well voltage Vwell pre-generated from the second voltage regulator is applied, the selected word line voltage SELWL is Vud2 at time t3 without a settling time, and is Vud3 at time t5.

The time for which the underdrive voltage is applied may be a preset time, and may be relatively shorter than the time for which the read voltage Vread is applied. As the negative level of the underdrive voltage increases, the settling time increases. Due to the increased settling time, in an embodiment, the effect of lowering the voltage level of the selected word line by applying the underdrive voltage having a negative level may be reduced. The word “preset” as used herein with respect to a parameter, such as a preset time, means that a value for the parameter is determined prior to the parameter being used in a process or algorithm. For some embodiments, the value for the parameter is determined before the process or algorithm begins. In other embodiments, the value for the parameter is determined during the process or algorithm but before the parameter is used in the process or algorithm.

According to an embodiment of the present disclosure, even if the negative level of the underdrive voltage is relatively large, the underdrive voltage may be applied to the selected word line without a settling time. Therefore, in an embodiment, the performance of the underdrive operation of lowering the voltage level of the selected word line may be improved even when an underdrive voltage having a high negative level is applied to the selected word line for a short period of time.

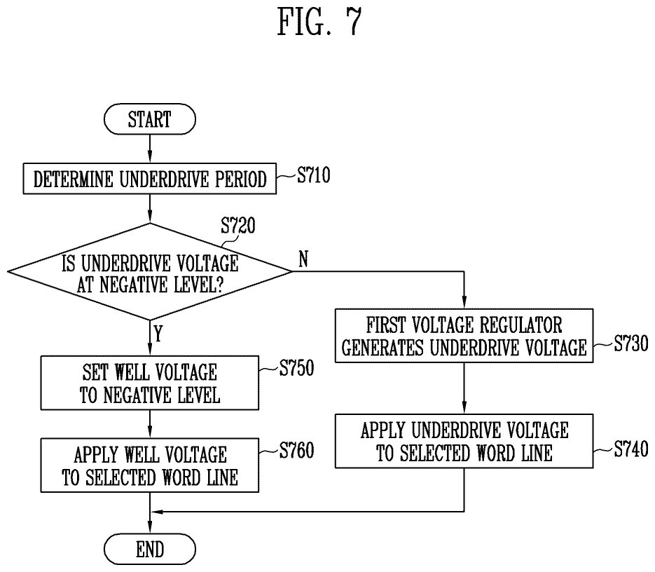

FIG. 7 is a flowchart illustrating a method of applying an underdrive voltage to a selected word line according to an embodiment of the present disclosure.

Referring to FIG. 7, the memory device may apply an underdrive voltage lower than an operating voltage to a selected word line before applying the operating voltage to the selected word line. The underdrive voltage may lower the voltage level of the selected word line. In the case where the underdrive voltage is at a negative level, the control logic may control the voltage regulator that generates a well voltage to generate the underdrive voltage earlier than the voltage regulator that generates the operating voltage. The control logic may transmit the generated underdrive voltage to the address decoder through a switching operation so that the underdrive voltage having a negative level can be applied to the selected word line without a settling time.

At step S710, the control logic may determine an underdrive period. Based on the operating voltage applied to memory cells connected to the selected word line, the control logic may determine the underdrive period during which the underdrive voltage lower than the operating voltage is applied to the selected word line. The underdrive period may be a period of applying the underdrive voltage to the selected word line for a preset time before the operating voltage generated from the first voltage regulator is applied to the selected word line.

At step S720, the control logic may determine whether the underdrive voltage is at a negative level. In the case where the underdrive voltage is at a positive level, the process may proceed to steps S730 and S740. In the case where the underdrive voltage is at a negative level, the process may proceed to steps S750 and S760.

At step S730, the first voltage regulator may sequentially generate the operating voltage and the underdrive voltage. The generated operating voltage and underdrive voltage may be transmitted to the address decoder. At step S740, the address decoder may apply the received operating voltage and underdrive voltage to the selected word line.

At step S750, the control logic may control the second voltage regulator to set the well voltage to a negative level. The control logic may generate a well voltage control signal for setting the well voltage to a negative level, in response to the underdrive voltage being at a negative voltage, and transmit the generated well voltage control signal to the second voltage regulator. A program voltage may be applied to the selected word line. The control logic may transfer the well voltage control signal earlier by a first time period than the underdrive period. The first time period may be determined based on the magnitude of the negative level.

At step S760, the control logic may apply a well voltage to the selected word line during the underdrive period in response to the underdrive voltage being at a negative level. The control logic may generate a switching signal for connecting the address decoder to the second voltage regulator and transmitting the generated switching signal to the voltage transfer circuit. The voltage transfer circuit may transfer the well voltage set to a negative level to an address decoder based on the switching signal. The address decoder may apply the well voltage to the selected word line.

The description of each step in FIG. 7 may correspond to the description provided for FIGS. 1 to 6.

In a memory device and a method of applying an underdrive voltage according to some embodiments, a negative underdrive voltage is generated from a well voltage regulator before an underdrive voltage is applied to a selected word line. During an underdrive period, in an embodiment, the generated negative underdrive voltage is applied to the selected word line. Therefore, in an embodiment, influence of a settling time according to response characteristics of the voltage regulator may be reduced, thereby improving the performance of an underdrive operation.

What is claimed is:

1. A memory device comprising:
a memory cell array including memory cells connected to a selected word line;
a first voltage regulator configured to generate an underdrive voltage having a voltage level lower than an operating voltage applied to the selected word line;
an address decoder including a plurality of transistors, and configured to apply, to the selected word line, a voltage received during an underdrive period during which the underdrive voltage is applied to the selected word line;
a second voltage regulator configured to generate a well voltage to be applied to the plurality of transistors;
a voltage transfer circuit configured to transfer the underdrive voltage or the well voltage to the address decoder; and
a control logic configured, in response to the underdrive voltage being at a negative level, to control the second voltage regulator to set the well voltage to the negative level before the underdrive period, and to control the voltage transfer circuit to transfer the well voltage set to the negative level to the address decoder during the underdrive period.

2. The memory device according to claim 1, wherein the operating voltage includes at least one of a read voltage, an erase voltage or a verify voltage.

3. The memory device according to claim 1, wherein the control logic generates a well voltage control signal for setting the well voltage to the negative level based on the operating voltage.

4. The memory device according to claim 3, wherein the control logic transfers the well voltage control signal to the second voltage regulator earlier by a first time period than the underdrive period, based on a magnitude of the negative level.

5. The memory device according to claim 4, wherein:
the control logic determines the first time period such that as the magnitude of the negate level increases, a length of the first time period increases, and
the first time period is a time required for the well voltage to reach the negative level.

6. The memory device according to claim 1, wherein the voltage transfer circuit includes a first switch connecting the first voltage regulator to the address decoder, and a second switch connecting the second voltage regulator to the address decoder.

7. The memory device according to claim 6, wherein the control logic, in response to the underdrive voltage being at a positive level, generates a first switching signal for turning on the first switch and turning off the second switch.

8. The memory device according to claim 7, wherein the control logic, in response to the underdrive voltage being at the negative level, generates a second switching signal for turning off the first switch and turning on the second switch during the underdrive period.

9. A method of operating a memory device, comprising:
based on an operating voltage applied to memory cells connected to a selected word line, determining an underdrive period during which an underdrive voltage lower than the operating voltage is applied to the selected word line;
in response to the underdrive voltage being at a negative level, setting a well voltage applied to transistors included in an address decoder to the negative level; and
in response to the underdrive voltage being at a negative level, applying the well voltage to the selected word line during the underdrive period.

10. The method according to claim 9, wherein the underdrive period is a period of applying the underdrive voltage to the selected word line for a preset time before the operating voltage generated from a first voltage regulator is applied to the selected word line.

11. The method according to claim 10, wherein setting the well voltage to the negative level comprises:
generating a well voltage control signal for setting the well voltage to the negative level, in response to the underdrive voltage being at the negative level; and
transferring the well voltage control signal to a second voltage regulator configured to generate the well voltage earlier by a first time period than the underdrive period.

12. The method according to claim 11, wherein the first time period is determined based on a magnitude of the negative level.

13. The method according to claim 12, wherein applying the well voltage to the selected word line comprises:
generating a switching signal for connecting the address decoder to the second voltage regulator in response to the underdrive voltage being at the negative level; and
applying the well voltage set to the negative level to the selected word line based on the switching signal.

14. A method of operating a memory device, comprising:
determining a first underdrive period during which a first underdrive voltage lower than a first operating voltage to be applied to memory cells connected to a selected word line is applied to the selected word line;
in response to the first underdrive voltage to be generated from a first voltage regulator configured to generate the first operating voltage being at a first negative level, generating a first well voltage corresponding to the first underdrive voltage earlier by a first time period than the first underdrive period by a second voltage regulator configured to generate a well voltage to be applied to transistors included in an address decoder;
applying the first well voltage generated from the second voltage regulator to the selected word line during the first underdrive period;
determining a second underdrive period during which a second underdrive voltage lower than a second operating voltage applied to the memory cells is applied to the selected word line;
in response to the second underdrive voltage to be generated from the first voltage regulator being at a second negative level, generating by the second voltage regulator a second well voltage corresponding to the second underdrive voltage earlier by a second time period than the second underdrive period; and
applying the second well voltage generated from the second voltage regulator to the selected word line during the second underdrive period.

15. The method according to claim 14, wherein generating the first well voltage comprises:
generating a first well voltage control signal for changing a level of the first well voltage based on the first underdrive voltage; and
setting, by the second voltage regulator, the first well voltage to the first negative level based on the first well voltage control signal.

16. The method according to claim 15, wherein applying the first well voltage comprises:
changing connection between the address decoder and the first voltage regulator to connection between the address decoder and the second voltage regulator; and
applying the first well voltage set to the first negative level to the selected word line.

17. The method according to claim 14, wherein generating the second well voltage comprises:
generating a second well voltage control signal for changing a level of the second well voltage based on the second underdrive voltage; and
setting, by the second voltage regulator, the second well voltage to the second negative level based on the second well voltage control signal.

18. The method according to claim 17, wherein applying the second well voltage comprises:
changing connection between the address decoder and the first voltage regulator to connection between the address decoder and the second voltage regulator; and
applying the second well voltage set to the second negative level to the selected word line.
